(19) United States
(12) Patent Application Publication
(10) Pub. No.: US 2001/0008124 A1
(43) Pub. Date: Jul. 19, 2001

(54) SUBSTRATE COOLING APPARATUS AND SEMICONDUCTOR MANUFACTURING APPARATUS

(76) Inventors: NOBUHIRO JIWARI, OSAKA (JP); SHINICHI IMAI, OSAKA (JP); HIDEO NIKOH, SHIGA (JP)

Correspondence Address: JAMES E. LEDBETTER, ESQ, STEVENS,DAVIS, MILLER & MOSHER, LLP, 1615 L STREET NW, SUITE 850, P.O. BOX 34387, WASHINGTON, DC, 200434387

(21) Appl. No.: 08/848,654

(22) Filed: Apr. 29, 1997

(30) Foreign Application Priority Data
Apr. 30, 1996 (JP) 109082/1996

(51) Int. Cl. C23C 16/00; H01L 21/00

(52) U.S. Cl. 118/728; 156/345

(57) ABSTRACT

The substrate cooling apparatus disclosed in the present invention comprises a semiconductor substrate holding electrode with a groove for conducting cooling gas formed in its holding surface for holding a semiconductor substrate thereon, wherein an inlet port for the substrate cooling gas is formed within 5 mm of the radially outermost edge of the semiconductor substrate holding electrode in such a manner as to connect with the groove from a surface of the electrode other than the holding surface thereof. When the semiconductor substrate is cooled by the substrate cooling apparatus, temperature difference within the substrate surface is small, and the substrate temperature is uniform through to the peripheral portions of the substrate. When this substrate cooling apparatus is used in a semiconductor manufacturing apparatus, semiconductor devices with stable device characteristics can be fabricated on the semiconductor substrate.

### BACKGROUND OF THE INVENTION

1. Field of the Invention

The present invention relates to a substrate cooling apparatus for cooling a semiconductor substrate and a semiconductor manufacturing apparatus using the substrate cooling apparatus.

2. Description of the Prior Art

In the prior art, the predominant type of substrate cooling apparatus used for cooling semiconductor substrates in the manufacturing process of semiconductor devices has been the type in which only a substrate cooling gas inlet port is provided in the center of a semiconductor substrate holding electrode, the semiconductor substrate held thereon being cooled with the cooling gas introduced through the inlet port. No apparatus have ever been available that are provided with a gas inlet port within 5 mm of the radially outermost edge of the semiconductor substrate holding electrode.

Example in which such prior art substrate cooling apparatus is used in dry etching will be described with reference to FIG. 11. FIG. 11(a) shows the substrate temperature distribution within the surface of a semiconductor substrate 20 during the process, FIG. 11(b) shows the etching profile in the center portion of the substrate, and FIG. 11(c) shows the etching profile in a peripheral portion of the substrate.

FIG. 12 shows the construction of a dry etching apparatus using the prior art substrate cooling apparatus. In the figure, reference numeral 21 is a semiconductor substrate holding electrode, 22 is a gas inlet port, 24 is a semiconductor substrate, such as a silicon wafer, held on the semiconductor substrate holding electrode 21, 23 is a groove formed in the holding surface of the semiconductor substrate holding electrode 21 for holding the semiconductor substrate 24 thereon, and 25 is a vacuum reaction chamber. FIG. 12 shows the construction in which the gas inlet port 22 is formed near the periphery of the semiconductor substrate holding electrode 21. In the construction, substrate cooling gas, such as helium, is introduced through the gas inlet port 22 so that the semiconductor substrate 24 is cooled with the substrate cooling gas flowing through the groove 23.

In the substrate cooling apparatus in which only the substrate cooling gas inlet port is provided in the substrate holding electrode, as in the prior art, the substrate cooling gas once introduced is not vented outside, resulting in poor cooling efficiency and, hence, increasing the temperature difference between the center and peripheral portions of the substrate, as shown in FIG. 11(a). This has lead to the problem that the etching profiles are different between the substrate center portions, shown in FIG. 11(b), and the substrate peripheral portions, shown in FIG. 11(c).

The large temperature difference within the substrate has also caused the problem that temperature-dependent characteristics vary greatly within the substrate surface. Particularly, in the case of the substrate cooling apparatus in which the substrate cooling gas inlet port is provided near the periphery of the semiconductor substrate holding electrode, the density of the substrate cooling gas decreases at the peripheral portions of the substrate outside the inlet port, tending to cause the substrate temperature to rise at the peripheral portions. If the inlet port is formed 20 mm inside of the periphery of the semiconductor substrate, for example, the substrate temperature is low at portions more than 20 mm away from the periphery and high at potions within 20 mm of the periphery. This causes variations of characteristics within the substrate surface. Since a semiconductor substrate is normally used up to 5 mm inside of its periphery for production of devices, the problem has been that the device characteristics vary and the number of viable chips that can be produced from a single substrate therefore decreases.

Furthermore, in the semiconductor manufacturing apparatus shown in FIG. 12, since only the substrate cooling gas inlet port 22 is provided in the semiconductor substrate holding electrode 21, the substrate cooling gas flowing through the groove 23 leaks into the interior of the vacuum reaction chamber 25. This causes variations in process conditions, and hence variations in device characteristics.

In the case of a semiconductor manufacturing apparatus in which an antenna for plasma generation is mounted encircling the reaction chamber, radiant heat around the plasma rises in temperature, increasing the temperature of the substrate at the peripheral portions thereof; the resulting problem has been variations of characteristics within the substrate surface. Further, in the case of a semiconductor manufacturing apparatus in which an antenna for plasma generation is mounted on top of the reaction chamber, radiant heat in the center of the plasma rises in temperature, increasing the temperature of the substrate at its center portion; this also has lead to the problem of characteristic variations within the substrate surface.

### SUMMARY OF THE INVENTION

It is an object of the present invention to provide a substrate cooling apparatus that reduces the temperature difference within the substrate surface, and that achieves uniform temperature distribution throughout the substrate up to the peripheral portions thereof and thus ensures stable device characteristics. It is also an object of the invention to provide a semiconductor manufacturing apparatus that reduces the temperature difference within the substrate surface, and that prevents substrate cooling gas from leaking into the reaction chamber and thus ensures stable device characteristics.

The invention provides a substrate cooling apparatus comprising: a semiconductor substrate holding electrode with a groove formed in a holding surface thereof for holding a semiconductor substrate thereon; and an inlet port for substrate cooling gas, formed within 5 mm of the radially outermost edge of the semiconductor substrate holding electrode in such a manner as to connect with the groove from a surface of the electrode other than the holding surface. In this way, by forming the inlet port for substrate cooling gas within 5 mm of the radially outermost edge of the semiconductor substrate holding electrode, the substrate temperature becomes uniform up to the peripheral portions thereof, so that stable device characteristics can be obtained even if the semiconductor substrate is used up to 5 mm inside of its periphery for device production.

The invention also provides a substrate cooling apparatus comprising: a semiconductor substrate holding electrode with a groove formed in a holding surface thereof for holding a semiconductor substrate thereon; an inlet port for substrate cooling gas, formed through the semiconductor substrate holding electrode in such a manner as to connect with the groove from a surface of the electrode other than the holding surface; and an outlet port for substrate cooling gas, formed through the semiconductor substrate holding electrode in such a manner as to connect with the groove from a surface of the electrode other than the holding surface. In this way, by forming the inlet port and outlet port for substrate cooling gas through the semiconductor substrate holding electrode, the substrate cooling gas can be vented outside through the outlet port, which serves to improve cooling efficiency and achieves uniform temperature distribution throughout the semiconductor substrate.

The invention also provides a substrate cooling apparatus comprising: a semiconductor substrate holding electrode with a groove formed in a holding surface thereof for holding a semiconductor substrate thereon; an inlet port for substrate cooling gas, formed through a peripheral portion of the semiconductor substrate holding electrode in such a manner as to connect with the groove from a surface of the electrode other than the holding surface; and an outlet port for substrate cooling gas, formed through a center portion of the semiconductor substrate holding electrode in such a manner as to connect with the groove from a surface of the electrode other than the holding surface. In this way, by forming the inlet port for substrate cooling gas through a peripheral portion of the semiconductor substrate holding electrode and the outlet port through a center portion of the semiconductor substrate holding electrode, the substrate cooling gas can be vented outside through the outlet port, which serves to improve cooling efficiency and achieves uniform temperature distribution throughout the semiconductor substrate.

The invention also provides a substrate cooling apparatus comprising: a semiconductor substrate holding electrode with a groove formed in a holding surface thereof for holding a semiconductor substrate thereon; an inlet port for substrate cooling gas, formed within 5 mm of the radially outermost edge of the semiconductor substrate holding electrode in such a manner as to connect with the groove from a surface of the electrode other than the holding surface; and an outlet port for substrate cooling gas, formed through a center portion of the semiconductor substrate holding electrode in such a manner as to connect with the groove from a surface of the electrode other than the holding surface. In this way, by forming the inlet port and outlet port for substrate cooling gas through the semiconductor substrate holding electrode, the substrate cooling gas can be vented outside through the outlet port, which serves to improve cooling efficiency and achieves uniform temperature distribution throughout the semiconductor substrate. Further, by forming the inlet port for substrate cooling gas within 5 mm of the radially outermost edge of the semiconductor substrate holding electrode, the substrate temperature becomes uniform up to the peripheral portions thereof, so that stable device characteristics can be obtained even if the semiconductor substrate is used up to 5 mm inside of its periphery for device production.

The invention also provides a substrate cooling apparatus comprising: a semiconductor substrate holding electrode with a groove formed in a holding surface thereof for holding a semiconductor substrate thereon; an inlet port for substrate cooling gas, formed through a center portion of the semiconductor substrate holding electrode in such a manner as to connect with the groove from a surface of the electrode other than the holding surface; and an outlet port for substrate cooling gas, formed through a peripheral portion of the semiconductor substrate holding electrode in such a manner as to connect with the groove from a surface of the electrode other than the holding surface. In this way, by forming the inlet port for substrate cooling gas through a center portion of the semiconductor substrate holding electrode and the outlet port through a peripheral portion of the semiconductor substrate holding electrode, the substrate cooling gas can be vented outside through the outlet port, which serves to improve cooling efficiency and achieves uniform temperature distribution throughout the semiconductor substrate.

The invention also provides a substrate cooling apparatus comprising: a semiconductor substrate holding electrode with a groove formed in a holding surface thereof for holding a semiconductor substrate thereon; an inlet port for substrate cooling gas, formed through a center portion of the semiconductor substrate holding electrode in such a manner as to connect with the groove from a surface of the electrode other than the holding surface; and an outlet port for substrate cooling gas, formed within 5 mm of the radially outermost edge of the semiconductor substrate holding electrode in such a manner as to connect with the groove from a surface of the electrode other than the holding surface. In this way, by forming the inlet port and outlet port for substrate cooling gas through the semiconductor substrate holding electrode, the substrate cooling gas can be vented outside through the outlet port, which serves to improve cooling efficiency and achieves uniform temperature distribution throughout the semiconductor substrate. Further, by forming the outlet port for substrate cooling gas within 5 mm of the radially outermost edge of the semiconductor substrate holding electrode, the substrate temperature becomes uniform up to the peripheral portions thereof, so that stable device characteristics can be obtained even if the semiconductor substrate is used up to 5 mm inside of its periphery for device production.

Furthermore, the invention provides a semiconductor manufacturing apparatus incorporating the above-described substrate cooling apparatus, wherein an antenna is provided for generating plasma within a vacuum reaction chamber in which a semiconductor substrate is placed. According to the semiconductor manufacturing apparatus of the invention, since the temperature distribution within the semiconductor substrate becomes uniform over a wide range, semiconductor devices with stable characteristics can be fabricated on the semiconductor substrate, and the fabrication yield improves. Further, by providing an outlet port for substrate cooling gas, the substrate cooling gas can be vented outside through the outlet port, which serves to prevent the cooling gas from leaking into the vacuum reaction chamber and thus prevent variations of device characteristics due to variations in process conditions. When the antenna for plasma generation is mounted encircling the vacuum reaction chamber, radiant heat around the plasma rises in temperature, but by forming the inlet port for substrate cooling gas through a peripheral portion of the semiconductor substrate holding electrode and the outlet port in a center portion thereof, the plasma temperature and the semiconductor substrate temperature cancel each other, and a uniform temperature distribution can be obtained throughout the semiconductor substrate. When the antenna for plasma generation is mounted on the top of the vacuum reaction chamber, radiant heat in the center of the plasma rises in temperature, but by forming the inlet port for substrate cooling gas through a center portion of the semiconductor substrate holding electrode and the outlet port in a peripheral portion thereof, the plasma temperature and the semiconductor substrate temperature cancel each other, and a uniform temperature distribution can be obtained throughout the semiconductor substrate.

### BRIEF DESCRIPTION OF THE DRAWINGS

FIG. 1 is a conceptual diagram of a substrate cooling apparatus according to a first embodiment of the present invention;

FIG. 2 is a temperature distribution diagram for a semiconductor substrate when the substrate cooling apparatus according to the first embodiment of the present invention is used;

FIG. 3 is a conceptual diagram of a substrate cooling apparatus according to a second embodiment of the present invention;

FIG. 4 is a temperature distribution diagram for a semiconductor substrate when the substrate cooling apparatus according to the second embodiment of the present invention is used;

FIG. 5 is a conceptual diagram of a semiconductor manufacturing apparatus according to a third embodiment of the present invention;

FIG. 6 is a temperature distribution diagram for a semiconductor substrate when the semiconductor manufacturing apparatus according to the third embodiment of the present invention is used;

FIG. 7 is a conceptual diagram of a substrate cooling apparatus according to a fourth embodiment of the present invention;

FIG. 8 is a temperature distribution diagram for a semiconductor substrate when the substrate cooling apparatus according to the fourth embodiment of the present invention is used;

FIG. 9 is a conceptual diagram of a semiconductor manufacturing apparatus according to a fifth embodiment of the present invention;

FIG. 10 is a temperature distribution diagram for a semiconductor substrate when the semiconductor manufacturing apparatus according to the fifth embodiment of the present invention is used;

FIGS. 11(a), (b), and (c) are diagrams showing a temperature distribution within a semiconductor substrate, an etching profile in the center of the substrate, and an etching profile in a peripheral portion of the substrate, when a prior art substrate cooling apparatus is used;

FIG. 12 is a conceptual diagram of a semiconductor manufacturing apparatus using the prior art substrate cooling apparatus.

### DESCRIPTION OF THE PREFERRED EMBODIMENTS

Embodiment 1

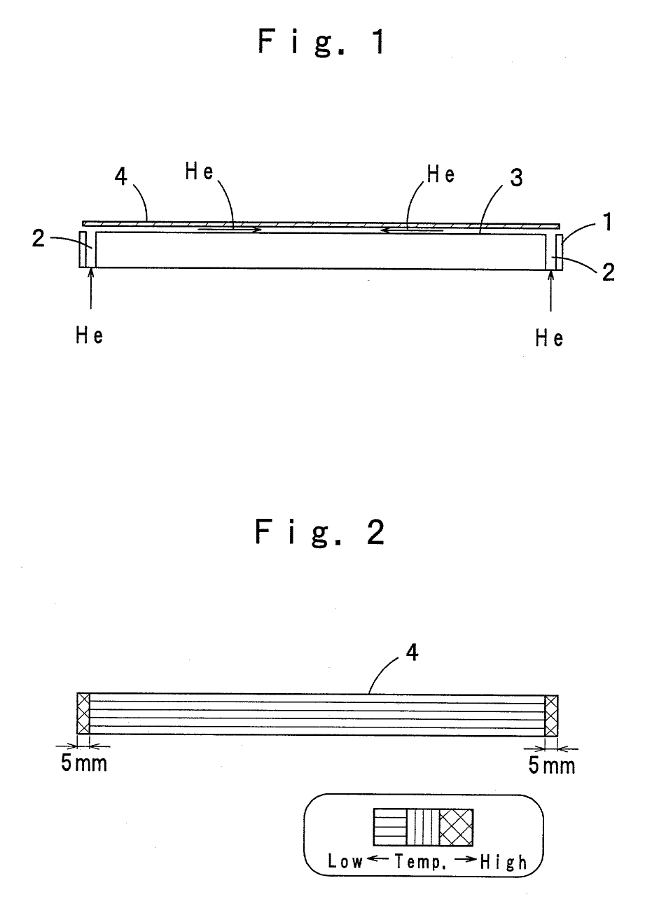

A substrate cooling apparatus according to a first embodiment of the present invention will be described with reference to FIGS. 1 and 2.

FIG. 1 is a diagram showing the construction of the substrate cooling apparatus, wherein reference numeral 1 is a semiconductor substrate holding electrode, 4 is a semiconductor substrate, such as a silicon wafer, held on the semiconductor substrate holding electrode 1, 3 is a groove formed in the holding surface of the semiconductor substrate holding electrode 1 for holding the semiconductor substrate 4 thereon, and 2 is a gas inlet port opened through the semiconductor substrate holding electrode 1 from the surface thereof opposite to the substrate holding surface and connecting with the groove 3. The inlet port is formed within 5 mm of the radially outermost edge of the semiconductor substrate holding electrode 1.

When substrate cooling gas such as helium (He) is introduced through the inlet port 2, the substrate cooling gas flows through the groove 3 into which the inlet port 2 opens. The substrate cooling gas flowing through the groove 3 removes the heat from the semiconductor substrate 4 and thus cools the semiconductor substrate 4.

FIG. 2 shows the temperature distribution within the semiconductor substrate 4; as shown, the temperature is distributed uniformly throughout the substrate except the portions thereof within 5 mm of its periphery.

Thus, according to the first embodiment, the gas inlet port 2 formed within 5 mm of the periphery of the semiconductor substrate holding electrode 1 ensures that the portions of the substrate lying more than 5 mm away from the periphery are uniformly cooled, achieving uniform temperature distribution throughout the substrate including the peripheral portions thereof. This makes it possible to produce chips with stable characteristics from the substrate portion up to 5 mm inside of the periphery of the semiconductor substrate holding electrode 1, thus increasing the number of chips that can be produced from one substrate.

Embodiment 2

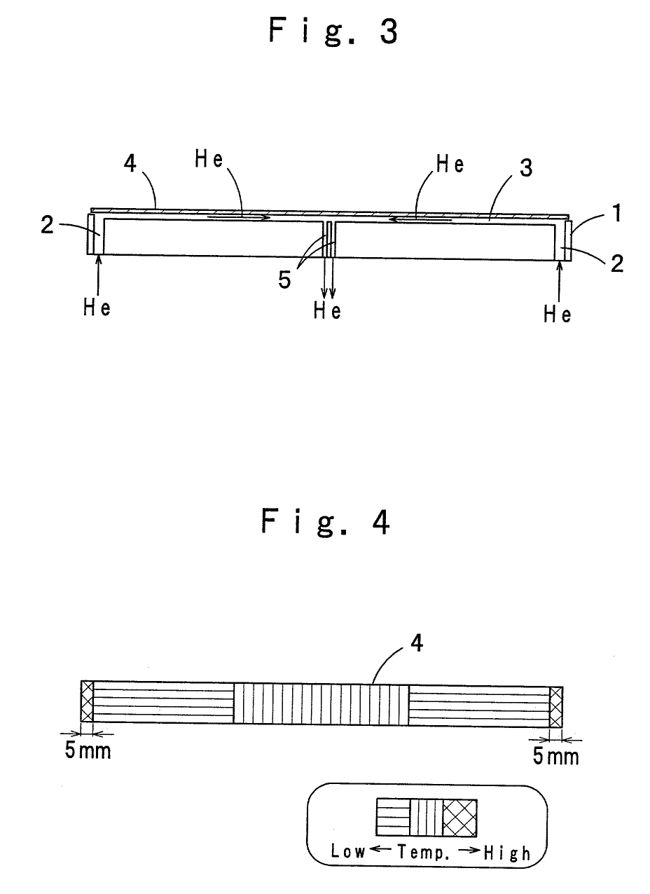

A substrate cooling apparatus according to a second embodiment of the invention will be described with reference to FIGS. 3 and 4. The same parts as those in the first embodiment are designated by the same reference numerals, and descriptions of such parts will not be repeated here.

The substrate cooling apparatus of this embodiment is characterized by the formation of a gas outlet port 5 formed in the center of the semiconductor substrate holding electrode 1 in addition to the gas inlet port 2 formed in the peripheral portion thereof. The inlet port 2 and the outlet port 5 are formed connecting the groove 3 with the surface of the electrode 1 opposite to the substrate holding surface. The inlet port 2 is formed within 5 mm of the radially outermost edge of the semiconductor substrate holding electrode 1, and the groove 3 is not opened into the periphery of the semiconductor substrate holding electrode 1.

When substrate cooling gas such as helium is introduced through the inlet port 2 formed in the peripheral portion, the substrate cooling gas flows through the groove 3 and exits through the outlet port 5. The substrate cooling gas removes the heat from the semiconductor substrate 4 and thus cools the semiconductor substrate 4.

FIG. 4 shows the temperature distribution within the semiconductor substrate 4; as shown, a nearly uniform temperature distribution can be achieved within the substrate portion more than 5 mm inside of the periphery of the semiconductor substrate 4, though the temperature slightly rises in the center of the semiconductor substrate 4 since the substrate cooling gas is warmed as it flows from the inlet port 2 in the peripheral portion toward the outlet port 5 in the center.

Thus, according to the second embodiment, with the provision of the inlet port 2 in the peripheral portion and the outlet port 5 in the center of the semiconductor substrate holding electrode 1, the warmed substrate cooling gas is allowed to exit through the outlet port 5, with the effect that temperature rise in the semiconductor substrate 4 is suppressed and the substrate surface is uniformly cooled, thus reducing temperature difference within the substrate. As a result, identical etching profiles can be obtained at the center and at the peripheral portion of the substrate; this improves device characteristics. Furthermore, it becomes possible to produce chips with stable characteristics from the substrate portion up to 5 mm inside of the periphery of the semiconductor substrate holding electrode 1, thus increasing the number of chips that can be produced from one substrate.

Embodiment 3

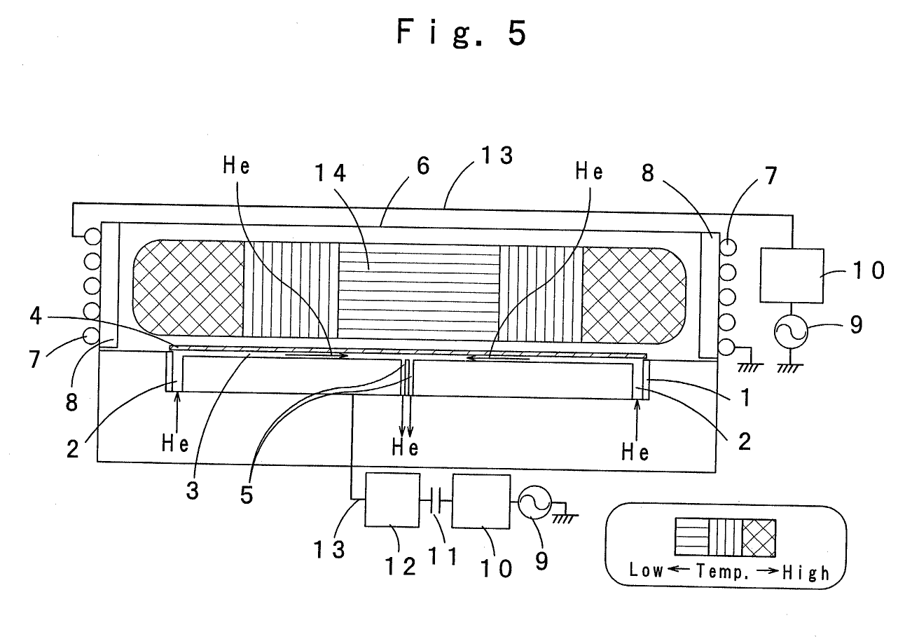

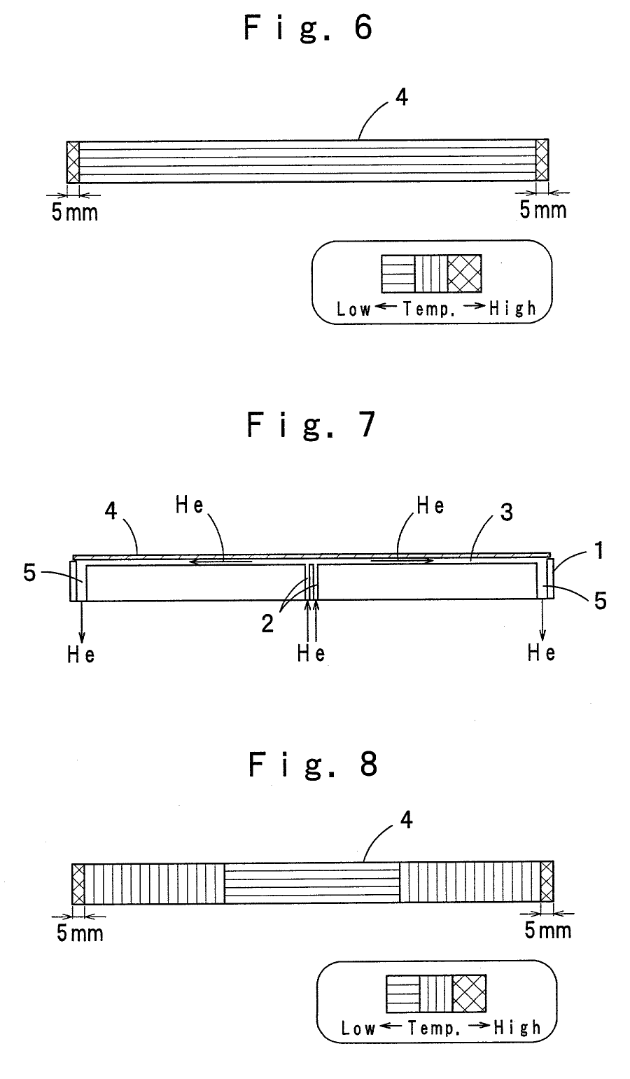

A semiconductor manufacturing apparatus according to a third embodiment of the present invention will be described with reference to FIGS. 5 and 6. The semiconductor manufacturing apparatus of this embodiment concerns a plasma etching apparatus that uses the substrate cooling apparatus of the second embodiment. The same parts as those in the second embodiment are designated by the same reference numerals, and descriptions of such parts will not be repeated here.

In FIG. 5, reference numeral 6 is a vacuum reaction chamber, 7 is an antenna mounted encircling the vacuum reaction chamber 6, 8 is a quartz dome, 9 is an AC power source, 10 is a matcher, 11 is a capacitor, 12 is a DC power source, 13 is an electrical line, and 14 is a plasma generated within the vacuum reaction chamber 6.

Process gas is introduced into the vacuum reaction chamber 6, and power is supplied from the AC power source 9 to generate the plasma 14. When the plasma 14 is generated, the temperature distribution of the plasma 14 is such that the temperature is higher in peripheral portions than in the center. When substrate cooling gas such as helium is introduced through the inlet port 2 formed in the peripheral portion of the semiconductor substrate holding electrode 1, the substrate cooling gas flows through the groove 3 and exits through the outlet port 5 formed in the center. The substrate cooling gas flowing through the groove 3 removes the heat from the semiconductor substrate 4 and thus cools the semiconductor substrate 4.

FIG. 6 shows the temperature distribution within the semiconductor substrate 4. When plasma is not formed, as in the second embodiment, the substrate temperature is slightly higher in the center than in the peripheral portions, as shown in FIG. 4. Accordingly, when the substrate cooling apparatus with the inlet port 2 formed in the peripheral portion and the outlet port 5 in the center is incorporated into the semiconductor manufacturing apparatus with the antenna 7 mounted encircling the vacuum reaction chamber 6 for generating the plasma 14, the temperature of the plasma and the temperature of the semiconductor substrate 4 cooled by the semiconductor substrate holding electrode 1 cancel each other, and a uniform temperature distribution is achieved throughout the semiconductor substrate 4 as shown in FIG. 6.

Thus, according to the third embodiment wherein the substrate cooling apparatus with the inlet port 2 formed in the peripheral portion and the outlet port 5 in the center is incorporated into the semiconductor manufacturing apparatus with the antenna 7 mounted encircling the vacuum reaction chamber 6 for generating the plasma 14, the substrate surface can be cooled uniformly, achieving a further reduction in the temperature difference. As a result, identical etching profiles can be obtained at the center and at the peripheral portion of the substrate; this improves device characteristics. Furthermore, it becomes possible to produce chips with stable characteristics from the substrate portion up to 5 mm inside of the periphery of the semiconductor substrate holding electrode 1, thus increasing the number of chips that can be produced from one substrate. Moreover, since the substrate cooling gas is vented outside through the outlet port 5, the substrate cooling gas is prevented from leaking into the vacuum reaction chamber 6; this also serves to improve device characteristics.

Embodiment 4

A substrate cooling apparatus according to a fourth embodiment of the present invention will be described with reference to FIGS. 7 and 8. The same parts as those in the second embodiment are designated by the same reference numerals, and descriptions of such parts will not be repeated here.

In this embodiment, the gas inlet port 2 is formed in the center of the semiconductor substrate holding electrode 1, while the gas outlet port 5 is formed in the peripheral portion of the semiconductor substrate holding electrode 1. The inlet port 2 and the outlet port 5 are formed connecting the groove 3 with the surface of the electrode 1 opposite to the substrate holding surface. The outlet port 5 is formed within 5 mm of the radially outermost edge of the semiconductor substrate holding electrode 1.

When substrate cooling gas such as helium is introduced through the inlet port 2 formed in the center, the substrate cooling gas flows through the groove 3 and exits through the outlet port 5 formed in the peripheral portion. The substrate cooling gas flowing through the groove 3 removes the heat from the semiconductor substrate 4 and thus cools the semiconductor substrate 4.

FIG. 8 shows the temperature distribution within the semiconductor substrate 4; as shown, a nearly uniform temperature distribution can be achieved throughout the substrate, though the temperature slightly rises in the peripheral portion of the semiconductor substrate 4 since the substrate cooling gas is warmed as it flows from the inlet port 2 in the center toward the outlet port 5 in the peripheral portion.

Thus, according to the fourth embodiment, with the provision of the inlet port 2 in the center and the outlet port 5 in the peripheral portion of the semiconductor substrate holding electrode 1, the substrate surface is uniformly cooled, thus reducing temperature difference within the substrate. As a result, identical etching profiles can be obtained at the center and at the peripheral portion of the substrate; this improves device characteristics. Furthermore, it becomes possible to produce chips with stable characteristics from the substrate portion up to 5 mm inside of the periphery of the semiconductor substrate holding electrode 1, thus increasing the number of chips that can be produced from one substrate.

Embodiment 5

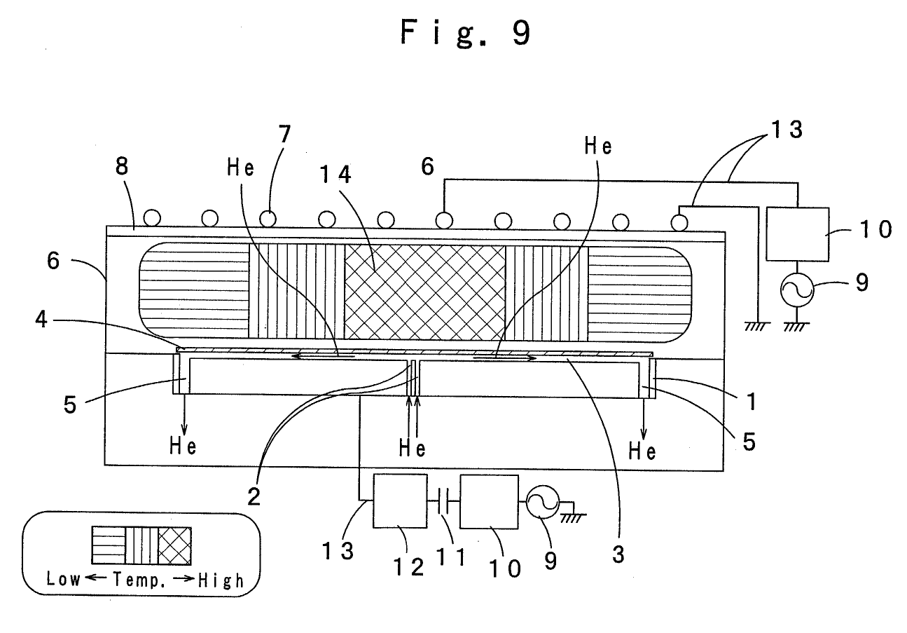

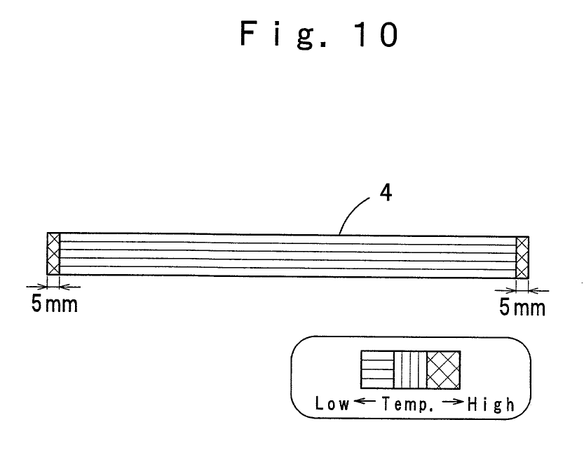

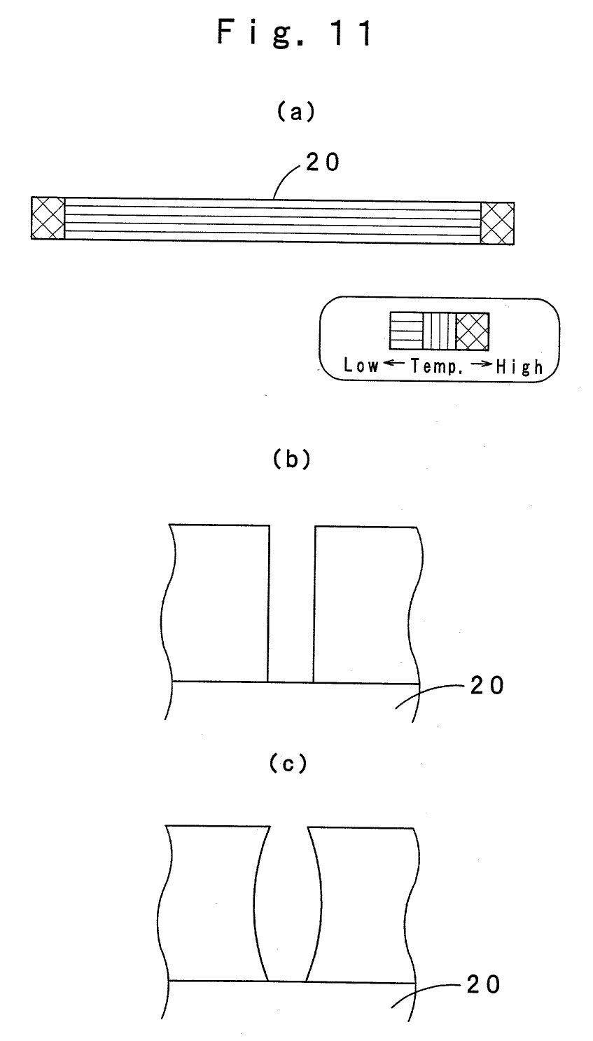

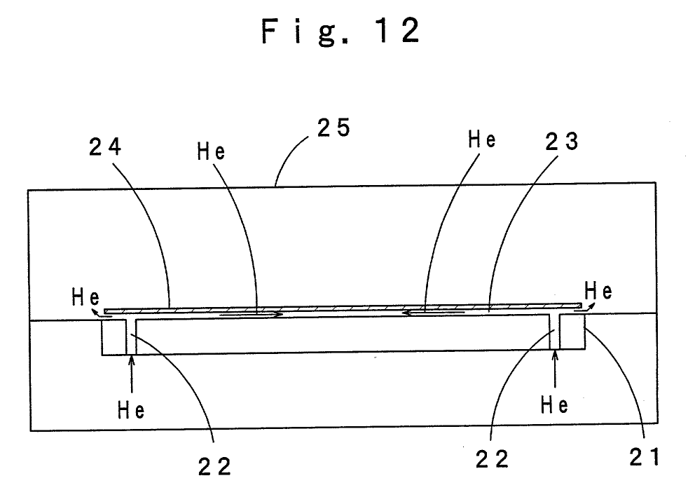

A semiconductor manufacturing apparatus according to a fifth embodiment of the present invention will be described with reference to FIGS. 9 and 10. This embodiment concerns a semiconductor manufacturing apparatus that uses the substrate cooling apparatus of the fourth embodiment and in which plasma is generated. The same parts as those in the third and fourth embodiments are designated by the same reference numerals, and descriptions of such parts will not be repeated here.

As shown in FIG. 9, the semiconductor substrate holding electrode 1 with the inlet port 2 formed in the center and the outlet port 5 in the peripheral portion is placed inside the vacuum reaction chamber 6, and the antenna 7 is mounted on the top of the reaction chamber 6 to generate plasma.

Process gas is introduced into the vacuum reaction chamber 6, and power is supplied from the AC power source 9 to generate the plasma 14. When the plasma 14 is generated, the temperature distribution of the plasma 14 is such that the temperature is higher in the center than in the peripheral portions. When substrate cooling gas such as helium is introduced through the inlet port 2 formed in the center of the semiconductor substrate holding electrode 1, the substrate cooling gas flows through the groove 3 and exits through the outlet port 5 formed in the peripheral portion. The substrate cooling gas flowing through the groove 3 removes the heat from the semiconductor substrate 4 and thus cools the semiconductor substrate 4.

FIG. 10 shows the temperature distribution within the semiconductor substrate 4. When plasma is not formed, as in the fourth embodiment, the substrate temperature is slightly higher in the peripheral portions than in the center portion, as shown in FIG. 8. Accordingly, when the substrate cooling apparatus with the inlet port 2 formed in the center and the outlet port 5 in the peripheral portion is incorporated into the semiconductor manufacturing apparatus with the antenna 7 mounted on the top of the vacuum reaction chamber 6 for generating the plasma 14, the temperature of the plasma and the temperature of the semiconductor substrate 4 cooled by the semiconductor substrate holding electrode 1 cancel each other, and a uniform temperature distribution is achieved throughout the semiconductor substrate 4 as shown in FIG. 10.

Thus, according to the fifth embodiment wherein the substrate cooling apparatus with the inlet port 2 formed in the center and the outlet port 5 in the peripheral portion is incorporated into the semiconductor manufacturing apparatus with the antenna 7 mounted on the top of the vacuum reaction chamber 6 for generating the plasma 14, the substrate surface can be cooled uniformly, achieving a further reduction in the temperature difference. As a result, identical etching profiles can be obtained at the center and at the peripheral portion of the substrate; this improves device characteristics. Furthermore, it becomes possible to produce chips with stable characteristics from the substrate portion up to 5 mm inside of the periphery of the semiconductor substrate holding electrode 1, thus increasing the number of chips that can be produced from one substrate. Moreover, since the substrate cooling gas is vented outside through the outlet port 5, the substrate cooling gas is prevented from leaking into the vacuum reaction chamber 6; this also serves to improve device characteristics.

In the second and third embodiments, the inlet port 2 is formed within 5 mm of the periphery of the semiconductor substrate holding electrode 1, but this limit of 5 mm is not an essential requirement, the only requirement being the formation of the inlet port 2 in a peripheral portion of the semiconductor substrate holding electrode 1. Likewise, in the fourth and fifth embodiments, the outlet port 5 is formed within 5 mm of the periphery of the semiconductor substrate holding electrode 1, but this limit of 5 mm is not an essential requirement, the only requirement being the formation of the outlet port 5 in a peripheral portion of the semiconductor substrate holding electrode 1.

A plasma etching apparatus has been described as an example of the semiconductor manufacturing apparatus incorporating the substrate cooling apparatus, but other dry etching apparatus may also be used.

Furthermore, the substrate cooling gas used is not limited to helium.

What is claimed is:

1. A substrate cooling apparatus comprising:
a semiconductor substrate holding electrode with a groove formed in a holding surface thereof for holding a semiconductor substrate thereon; and
an inlet port for substrate cooling gas, formed within 5 mm of the radially outermost edge of said semiconductor substrate holding electrode in such a manner as to connect with said groove from a surface of said electrode other than said holding surface.

2. A substrate cooling apparatus comprising:
a semiconductor substrate holding electrode with a groove formed in a holding surface thereof for holding a semiconductor substrate thereon;
an inlet port for substrate cooling gas, formed through said semiconductor substrate holding electrode in such a manner as to connect with said groove from a surface of said electrode other than said holding surface; and
an outlet port for substrate cooling gas, formed through said semiconductor substrate holding electrode in such a manner as to connect with said groove from a surface of said electrode other than said holding surface.

3. A substrate cooling apparatus comprising:
a semiconductor substrate holding electrode with a groove formed in a holding surface thereof for holding a semiconductor substrate thereon;
an inlet port for substrate cooling gas, formed through a peripheral portion of said semiconductor substrate holding electrode in such a manner as to connect with said groove from a surface of said electrode other than said holding surface; and
an outlet port for substrate cooling gas, formed through a center portion of said semiconductor substrate holding electrode in such a manner as to connect with said groove from a surface of said electrode other than said holding surface.

4. A substrate cooling apparatus comprising:
a semiconductor substrate holding electrode with a groove formed in a holding surface thereof for holding a semiconductor substrate thereon;
an inlet port for substrate cooling gas, formed within 5 mm of the radially outermost edge of said semiconductor substrate holding electrode in such a manner as to connect with said groove from a surface of said electrode other than said holding surface; and
an outlet port for substrate cooling gas, formed through a center portion of said semiconductor substrate holding electrode in such a manner as to connect with said groove from a surface of said electrode other than said holding surface.

5. A semiconductor manufacturing apparatus with a substrate cooling apparatus as set forth in claim 1, 2, 3, or 4, mounted inside a vacuum reaction chamber, wherein an antenna for generating plasma within said vacuum reaction chamber is mounted in such a manner as to encircle said vacuum reaction chamber.

6. A substrate cooling apparatus comprising:
a semiconductor substrate holding electrode with a groove formed in a holding surface thereof for holding a semiconductor substrate thereon;
an inlet port for substrate cooling gas, formed through a center portion of said semiconductor substrate holding electrode in such a manner as to connect with said groove from a surface of said electrode other than said holding surface; and
an outlet port for substrate cooling gas, formed through a peripheral portion of said semiconductor substrate holding electrode in such a manner as to connect with said groove from a surface of said electrode other than said holding surface.

7. A substrate cooling apparatus comprising:
a semiconductor substrate holding electrode with a groove formed in a holding surface thereof for holding a semiconductor substrate thereon;
an inlet port for substrate cooling gas, formed through a center portion of said semiconductor substrate holding electrode in such a manner as to connect with said groove from a surface of said electrode other than said holding surface; and
an outlet port for substrate cooling gas, formed within 5 mm of the radially outermost edge of said semiconductor substrate holding electrode in such a manner as to connect with said groove from a surface of said electrode other than said holding surface.

8. A semiconductor manufacturing apparatus with a substrate cooling apparatus as set forth in claim 1, 2, 6, or 7, mounted inside a vacuum reaction chamber, wherein an antenna for generating plasma within said vacuum reaction chamber is mounted on the top of said vacuum reaction chamber.
